(19) United States
(12) Patent Application Publication
(10) Pub. No.: US 2026/0011290 A1
(43) Pub. Date: Jan. 8, 2026

(54) SCAN DRIVER AND DISPLAY DEVICE INCLUDING THE SAME

(71) Applicant: Samsung Display Co., LTD., Yongin-si (KR)

(72) Inventors: Jun Hyun PARK, Yongin-si (KR); Young Wan SEO, Yongin-si (KR); So Il Yoon, Yongin-si (KR)

(21) Appl. No.: 19/084,544

(22) Filed: Mar. 19, 2025

(30) Foreign Application Priority Data
Jul. 8, 2024 (KR) 10-2024-0089771

(51) Int. Cl. G09G 3/32; G09G 3/3266

(52) U.S. Cl. CPC G09G 3/32; G09G 3/3266; G09G 2300/043; G09G 2310/0267; G09G 2330/021

(57) ABSTRACT

Provided are a scan driver and a display device including the same. A display device includes a pixel including a light-emitting element, and a first transistor configured to supply a driving current to the light-emitting element, a scan driver including a first oxide transistor, and configured to supply a scan signal to the pixel, a first active layer above a substrate, and including a first material, a first gate layer above the first active layer, a second gate layer above the first gate layer, and a second active layer above the second gate layer, including a second material that is different from the first material, and including a semiconductor region of the first transistor and a semiconductor region of the first oxide transistor, wherein a bias electrode of the first transistor and a bias electrode of the first oxide transistor are at different layers.

### CROSS-REFERENCE TO RELATED APPLICATION

The present application claims priority to, and the benefit of, Korean Patent Application No. 10-2024-0089771, filed on Jul. 8, 2024, in the Korean Intellectual Property Office, the entire disclosure of which is incorporated herein by reference.

### BACKGROUND

### 1. Field

One or more embodiments of the present disclosure relate to a scan driver, and a display device including the same.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display device may display an image without a backlight unit providing light to a display panel because each of pixels of the display panel includes light-emitting elements that may emit light by themselves.

The display device includes a plurality of pixels, data lines, and gate lines connected to the plurality of pixels, a data driver supplying data voltages to the data lines, and a scan driver supplying scan signals to the gate lines. The data driver and the scan driver may drive the plurality of pixels according to a corresponding frequency.

### SUMMARY

Aspects of embodiments of the present disclosure provide a scan driver capable of improving reliability of the scan driver by controlling a threshold voltage of an oxide transistor of the scan driver, and a display device including the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a display device including a pixel including a light-emitting element, and a first transistor configured to supply a driving current to the light-emitting element, a scan driver including a first oxide transistor, and configured to supply a scan signal to the pixel, a first active layer above a substrate, and including a first material, a first gate layer above the first active layer, a second gate layer above the first gate layer, and a second active layer above the second gate layer, including a second material that is different from the first material, and including a semiconductor region of the first transistor and a semiconductor region of the first oxide transistor, wherein a bias electrode of the first transistor and a bias electrode of the first oxide transistor are at different layers.

The bias electrode of the first transistor may be at the second gate layer, and the bias electrode of the first oxide transistor may be at the first gate layer.

The scan driver may further include a second oxide transistor including a semiconductor region at the second active layer, wherein a bias electrode of the second oxide transistor and the bias electrode of the first oxide transistor are at different layers.

The bias electrode of the second oxide transistor may be at the second gate layer, and the bias electrode of the first oxide transistor may be at the first gate layer.

The display device may further include a metal layer between the substrate and the first active layer, wherein the bias electrode of the second oxide transistor is at the first gate layer, and the bias electrode of the first oxide transistor is at the metal layer.

The display device may further include a metal layer between the substrate and the first active layer, wherein the bias electrode of the first transistor is at the second gate layer, and the bias electrode of the first oxide transistor is at the metal layer.

The scan driver may further include a fifth scan transistor configured to supply a first gate low voltage to an output node for outputting the scan signal based on a voltage of a first scan node, a sixth scan transistor configured to supply a first gate high voltage to the output node based on a voltage of a second scan node, a third scan transistor configured to initialize the voltage of the second scan node to the first gate low voltage based on the voltage of the first scan node, a second scan transistor configured to electrically connect the first scan node to a third scan node based on the first gate low voltage, and a first scan transistor configured to supply a start signal to the third scan node based on a first clock signal.

The first oxide transistor may be the first scan transistor, and the second oxide transistor may be the third scan transistor.

The scan driver may further include a seventh scan transistor for outputting a second gate low voltage as a carry signal based on the voltage of the second scan node, the second gate low voltage having an absolute value that is lower than an absolute value of the first gate low voltage.

The first oxide transistor may be the first scan transistor, and the second oxide transistor may be the third or seventh scan transistor.

The pixel may further include a second transistor configured to supply a data voltage to a first node that is a gate electrode of the first transistor, a third transistor configured to supply a reference voltage to the first node, a fourth transistor configured to discharge a first electrode of the light-emitting element to an initialization voltage, a fifth transistor configured to supply a driving voltage to a drain electrode of the first transistor, and a sixth transistor configured to electrically connect a second node that is a source electrode of the first transistor and a third node that is the first electrode of the light-emitting element to each other.

A semiconductor region of the second transistor may be at the second active layer, wherein the bias electrode of the first transistor and a bias electrode of the second transistor are at different layers.

The bias electrode of the first transistor may be at the second gate layer, wherein a bias electrode of the second transistor is at the first gate layer.

According to one or more embodiments of the present disclosure, there is provided a display device including a light-emitting element, a first transistor configured to supply a driving current to the light-emitting element, a second transistor configured to supply a data voltage to a first node that is a gate electrode of the first transistor, a third transistor configured to supply a reference voltage to the first node, a fourth transistor configured to discharge a first electrode of the light-emitting element to an initialization voltage, a fifth transistor configured to supply a driving voltage to a drain electrode of the first transistor, a sixth transistor configured to electrically connect a second node that is a source electrode of the first transistor and a third node that is the first electrode of the light-emitting element to each other, a first active layer above a substrate, and including a semiconductor region of the fifth transistor and a semiconductor region of the sixth transistor, a first gate layer above the first active layer, a second gate layer above the first gate layer, and a second active layer above the second gate layer, and including a semiconductor region of the first transistor and a semiconductor region of the second transistor, wherein a bias electrode of the first transistor and a bias electrode of the second transistor are at different layers.

The bias electrode of the first transistor may be at the second gate layer, and the bias electrode of the second transistor is at the first gate layer.

The display device may further include a metal layer between the substrate and the first active layer, wherein a bias electrode of the fifth transistor and a bias electrode of the sixth transistor are at the metal layer.

According to one or more embodiments of the present disclosure, there is provided a scan driver including a fifth scan transistor configured to supply a first gate low voltage to an output node based on a voltage of a first scan node, the output node for outputting a scan signal, a sixth scan transistor configured to supply a first gate high voltage to the output node based on a voltage of a second scan node, a third scan transistor configured to initialize the voltage of the second scan node to the first gate low voltage based on the voltage of the first scan node, a second scan transistor configured to electrically connect the first scan node to a third scan node based on the first gate low voltage, a first scan transistor configured to supply a start signal to the third scan node based on a second gate high voltage that is lower than the first gate high voltage, and a seventh scan transistor configured to output a second gate low voltage as a carry signal based on the voltage of the second scan node, the second gate low voltage having an absolute value that is lower than an absolute value of the first gate low voltage, wherein a bias electrode of the first scan transistor and a bias electrode of the seventh scan transistor are at different layers.

The scan driver may further include a first active layer above a substrate, and including a semiconductor region of the first scan transistor and a semiconductor region of the sixth scan transistor, a first gate layer above the first active layer, a second gate layer above the first gate layer, and a second active layer above the second gate layer, and including a semiconductor region of the first scan transistor and a semiconductor region of the seventh scan transistor.

The bias electrode of the first scan transistor may be at the first gate layer, wherein the bias electrode of the seventh scan transistor is at the second gate layer.

The scan driver may further include a metal layer between the substrate and the first active layer, wherein the bias electrode of the first scan transistor is at the metal layer, and wherein the bias electrode of the seventh scan transistor is at the second gate layer.

According to one or more embodiments of the present disclosure, there is provided an electronic device including a display device including a pixel including a light-emitting element, and a first transistor configured to supply a driving current to the light-emitting element, a scan driver including a first oxide transistor, and configured to supply a scan signal to the pixel, a first active layer above a substrate, and including a first material, a first gate layer above the first active layer, a second gate layer above the first gate layer, and a second active layer above the second gate layer, including a second material that is different from the first material, and including a semiconductor region of the first transistor and a semiconductor region of the first oxide transistor, wherein a bias electrode of the first transistor and a bias electrode of the first oxide transistor are at different layers.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, a head-mounted display (HMD), a virtual reality (VR) device, or an augmented reality (AR) device.

According to the aforementioned and other embodiments of the present disclosure, a bias electrode of a first transistor of a pixel and a bias electrode of a first oxide transistor of the scan driver are located at different respective layers, such that an influence of a bias voltage of the first oxide semiconductor may be adjusted to control a threshold voltage of the first oxide semiconductor, and reliability of the scan driver may be improved.

### BRIEF DESCRIPTION OF THE DRAWINGS

The above and other embodiments of the present disclosure will become more apparent by describing embodiments thereof with reference to the attached drawings, in which:

FIG. 1 is a perspective view illustrating a display device according to one or more embodiments;

FIG. 2 is a block diagram illustrating the display device according to one or more embodiments;

FIG. 3 is a block diagram illustrating a scan driver of the display device according to one or more embodiments;

FIG. 4 is a circuit diagram illustrating a stage of the scan driver in the display device according to one or more embodiments;

FIG. 5 is a circuit diagram illustrating a pixel of the display device according to one or more embodiments;

FIG. 6 is a cross-sectional view illustrating the display device according to one or more embodiments;

FIG. 7 is a cross-sectional view illustrating a display device according to one or more other embodiments;

FIG. 8 is a cross-sectional view illustrating a display device according to still one or more other embodiments;

FIG. 9 is a cross-sectional view illustrating a display device according to still one or more other embodiments; and

FIG. 10 is a cross-sectional view illustrating a display device according to still one or more other embodiments.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions, such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression, such as “at least one of A and/or B” may include A, B, or A and B. As used herein, the term “and/or” includes any and all combinations of one or more of the associated listed items. For example, the expression, such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

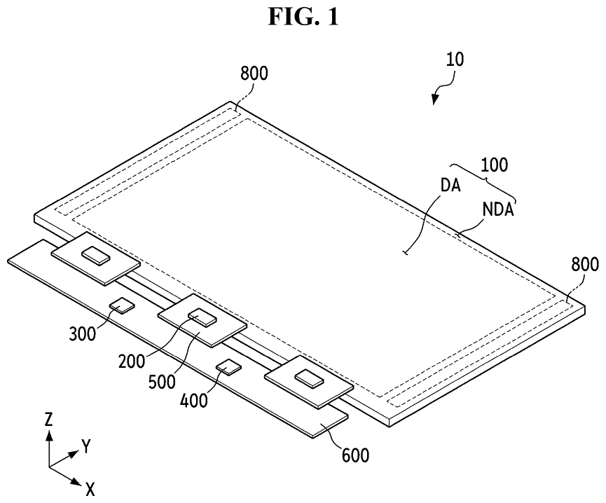

FIG. 1 is a perspective view illustrating a display device according to one or more embodiments.

Referring to FIG. 1, a display device 10 is a device that displays a moving image or a still image, and may be used as a display screen of various products such as televisions, laptop computers, monitors, billboards, and Internet of Things (IoT) device as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs). The display device 10 may also be a virtual reality (VR) device, an augmented reality (AR) device, and/or a head-mounted display device (HMD) (e.g., for implementing virtual reality and/or augmented reality).

The display device 10 may include a display panel 100, data drivers 200, a timing controller 300, a power supply unit 400, data circuit boards 500, a control circuit board 600, and scan drivers 800.

The display panel 100 may have a rectangular shape, in plan view, having long sides in an X-axis direction and short sides in a Y-axis direction crossing the X-axis direction. A corner where the long side in the X-axis direction and the short side in the Y-axis direction meet may be rounded with a corresponding curvature or right-angled. A shape of the display panel 100 in plan view is not limited to the rectangular shape, and may be other polygonal shapes, a circular shape, or an elliptical shape. The display panel 100 may be formed to be flat, but is not limited thereto. For example, the display panel 100 may include curved surface portions formed at left and right ends thereof and having a constant curvature or a variable curvature. The display panel 100 may be flexibly formed to be curved, bent, folded, or rolled.

The display panel 100 may include a display area DA displaying an image and a non-display area NDA located around the display area DA. The display area DA may occupy most of the area of the display panel 100. The display area DA may be located at the center of the display panel 100. The display area DA may include a plurality of pixels displaying the image.

Each of the plurality of pixels may include a light-emitting element emitting light. The light-emitting element may include at least one of an organic light-emitting diode (LED) including an organic light-emitting layer, a quantum dot LED including a quantum dot light-emitting layer, an inorganic LED including an inorganic semiconductor, and a micro LED, but is not limited thereto.

The non-display area NDA may be located adjacent to the display area DA. The non-display area NDA may be an area outside the display area DA. The non-display area NDA may be located to surround the display area DA. The non-display area NDA may be an edge area of the display panel 100.

The non-display area NDA may include the scan drivers 800, fan-out lines, and pad portions. The scan drivers 800 may supply scan signals to scan lines of the display area DA. The scan drivers 800 may be located at left and right edges of the non-display area NDA, but are not limited thereto. The fan-out lines may connect the data drivers 200 and data lines of the display area DA to each other. The pad portions may be electrically connected to the data circuit boards 500. The pad portions may be located at an edge of a lower side of the display panel 100, but are not limited thereto.

The data drivers 200 may output signals and voltages for driving the display panel 100. The data drivers 200 may supply data voltages to the data lines. The data drivers 200 may supply source voltages to power lines, and may supply scan control signals to the scan drivers 800. The data driver 200 may be formed as an integrated circuit (IC), and may be mounted on the data circuit board 500 in a chip on film (COF) manner. As another example, the data driver 200 may be mounted on the non-display area NDA of the display panel 100 in a chip-on-glass (COG) manner, a chip-on-plastic (COP) manner, or an ultrasonic bonding manner.

The timing controller 300 may be mounted on the control circuit board 600, and may receive digital video data and a timing synchronization signal supplied from a display driving system or from a graphic device through a user connector provided on the control circuit board 600. The timing controller 300 may align the digital video data to be suitable for a pixel arrangement structure based on the timing synchronization signal, and may supply the aligned digital video data to the data drivers 200. The timing controller 300 may generate a data control signal and a scan control signal based on the timing synchronization signal. The timing controller 300 may control a supply timing of the data voltage of the data driver 200 based on the data control signal, and may control a supply timing of the scan signal of the scan driver 800 based on the scan control signal.

The power supply unit 400 may be mounted on the control circuit board 600, and may supply source voltages to the display panel 100 and the data drivers 200. For example, the power supply unit 400 may generate a driving voltage, a common voltage, an initialization voltage, a bias voltage, a gate high voltage, a gate low voltage, or a reference voltage. The power supply unit 400 may supply the source voltages to drive the plurality of pixels and the data drivers 200.

The data circuit boards 500 may be located on the pad portions located at an edge of one side of the display panel 100. The data circuit boards 500 may be attached to the pad portions using conductive adhesive members, such as anisotropic conductive films. The data circuit boards 500 may be electrically connected to signal lines of the display panel 100 through the anisotropic conductive films. The display panel 100 may receive the data voltages and the source voltages through the data circuit boards 500. For example, the data circuit board 500 may be a flexible printed circuit board, a printed circuit board, or a flexible film, such as a chip on film.

The control circuit board 600 may be attached to the data circuit boards 500 using an anisotropic conductive film, a low-resistance and high-reliability material, such as a self-assembly anisotropic conductive paste (SAP), or the like. The control circuit board 600 may be electrically connected to the data circuit boards 500. The control circuit board 600 may be a flexible printed circuit board or a printed circuit board.

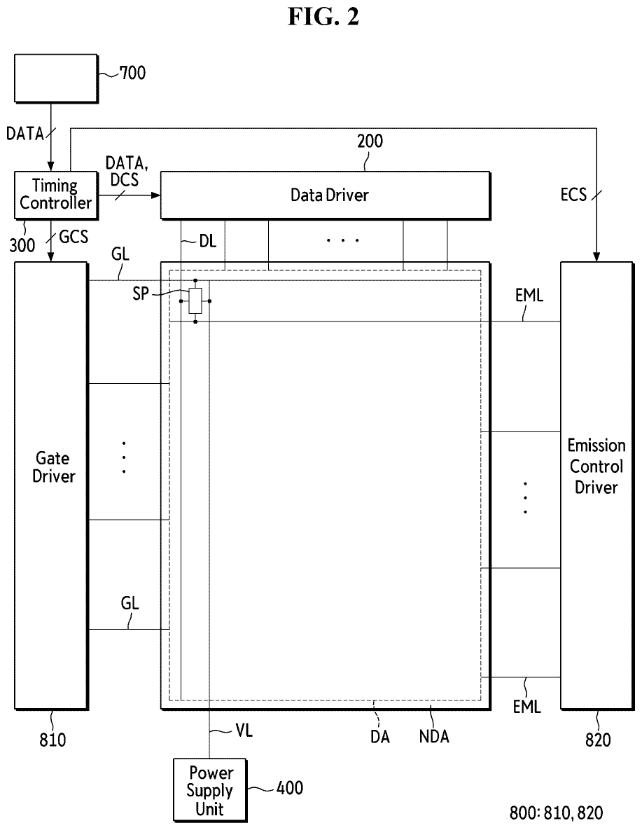

FIG. 2 is a block diagram illustrating the display device according to one or more embodiments.

Referring to FIG. 2, the display panel 100 may include a display area DA and a non-display area NDA. The display area DA may include pixels SP, gate lines GL, emission control lines EML, data lines DL, and voltage lines VL.

Each of a plurality of pixels SP may be connected to the gate line GL, the data line DL, the emission control line EML, and the voltage line VL. Each of the plurality of pixels SP may include at least one transistor, a light-emitting element, and a capacitor.

The gate lines GL may extend in the X-axis direction, and may be spaced apart from each other in the Y-axis direction crossing the X-axis direction. The gate lines GL may sequentially supply gate signals to the plurality of pixel SP.

The emission control lines EML may extend in the X-axis direction, and may be spaced apart from each other in the Y-axis direction. The emission control lines EML may sequentially supply emission signals to the plurality of pixels SP.

The data lines DL may extend in the Y-axis direction, and may be spaced apart from each other in the X-axis direction. The data lines DL may supply data voltages received from the data driver 200 to the pixels PX. The data voltage may determine luminance of each of the pixels SP.

The voltage lines VL may extend in the Y-axis direction, and may be spaced apart from each other in the X-axis direction. The voltage lines VL may supply source voltages to the plurality of pixels SP. The source voltage may include at least one of a driving voltage, a common voltage, an initialization voltage, a bias voltage, a gate high voltage, a gate low voltage, and a reference voltage. For example, the driving voltage may be a high potential voltage for driving the light-emitting element of the pixel SP, and the common voltage may be a low potential voltage for driving the light-emitting element of the pixel SP.

The data driver 200 may convert digital video data DATA into analog data voltages, and may supply the analog data voltages to the data lines DL. Gate signals of a gate driver 810 may select pixels SP to which the data voltages are supplied, and the selected pixels SP may receive the data voltages through the data lines DL.

The timing controller 300 may receive the digital video data DATA and timing signals from a graphic device 700. For example, the graphic device 700 may be a graphic card of the display device 10, but is not limited thereto. The timing controller 300 may control an operation timing of the data driver 200 by generating a data control signal DCS based on the timing signals, and by supplying the digital video data DATA and the data control signal DCS to the data driver 200. The timing controller 300 may control an operation timing of the gate driver 810 by generating a gate control signal GCS based on the timing signals, and by supplying the gate control signal GCS to the gate driver 810. The timing controller 300 may control an operation timing of an emission control driver 820 by generating an emission control signal ECS based on the timing signals, and by supplying the emission control signal ECS to the emission control driver 820. The timing controller 300 may vary a driving frequency of the display panel 100 based on an input frequency of the digital video data DATA of the graphic device 700.

The power supply unit 400 may be located on the control circuit board 600, and may supply source voltages to the data driver 200 and the display panel 100. The power supply unit 400 may generate a driving voltage, and may supply the driving voltage to a driving voltage line, and may generate a common voltage, and may supply the common voltage to a common electrode common to the light-emitting elements of the pixels. The power supply unit 400 may generate an initialization voltage, and may supply the initialization voltage to an initialization voltage line, and may generate a bias voltage, and may supply the bias voltage to a bias voltage line. The power supply unit 400 may generate a gate high voltage, and may supply the gate high voltage to a gate high voltage line, may generate a gate low voltage, and may supply the gate low voltage to a gate low voltage line, and may generate a reference voltage, and may supply the reference voltage to a reference voltage line.

The gate driver 810 may be located outside one side of the display area DA or on one side of the non-display area NDA, and the emission control driver 820 may be located outside the other side of the display area DA or on the other side of the non-display area NDA, but the present disclosure is not limited thereto. As another example, the gate driver 810 and the emission control driver 820 may be located on any one of one side and the other side of the non-display area NDA.

The gate driver 810 may include a plurality of scan transistors for generating gate signals based on the gate control signal GCS. The emission control driver 820 may include a plurality of scan transistors generating emission signals based on the emission control signal ECS. The gate driver 810 may supply the gate signals to the gate lines GL, and the emission control driver 820 may supply the emission signals to the emission control lines EML.

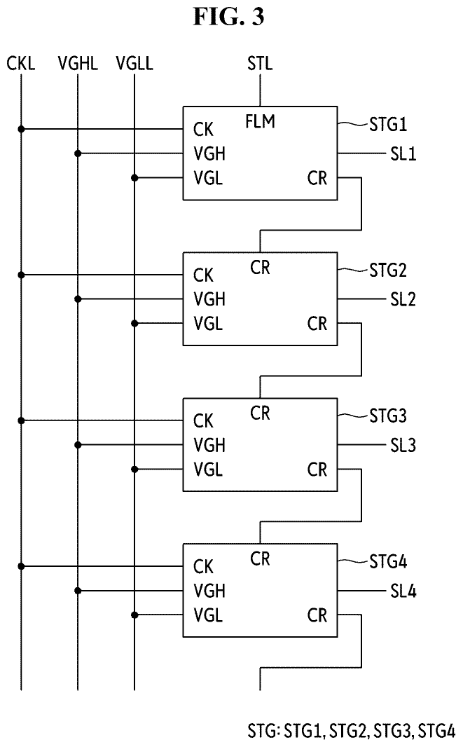

FIG. 3 is a block diagram illustrating a scan driver of the display device according to one or more embodiments.

Referring to FIG. 3, the scan driver 800 may include a plurality of stages STG. A clock line CKL may supply a clock signal CK to the stages STG. A gate high voltage line VGHL may supply a gate high voltage VGH to the stages STG, and a gate low voltage line VGLL may supply a gate low voltage VGL to the stages STG. The stages STG may generate scan signals, and may supply the scan signals to scan lines. The scan line may include the gate line GL and the emission control line EML of FIG. 2. The stages STG may include first to fourth stages STG1, STG2, STG3, and STG4.

The first stage STG1 may be connected to a start line STL and may receive a start signal FLM. The first stage STG1 may receive the clock signal CK, the gate high voltage VGH, and the gate low voltage VGL, and may supply a first scan signal to a first scan line SL1.

The second stage STG2 may receive a carry signal CR from the first stage STG1. The second stage STG2 may receive the clock signal CK, the gate high voltage VGH, and the gate low voltage VGL, and may supply a second scan signal to a second scan line SL2.

The third stage STG3 may receive a carry signal CR from the second stage STG2. The third stage STG3 may receive the clock signal CK, the gate high voltage VGH, and the gate low voltage VGL, and may supply a third scan signal to a third scan line SL3.

The fourth stage STG4 may receive a carry signal CR from the third stage STG3. The fourth stage STG4 may receive the clock signal CK, the gate high voltage VGH, and the gate low voltage VGL, and may supply a fourth scan signal to a fourth scan line SL4.

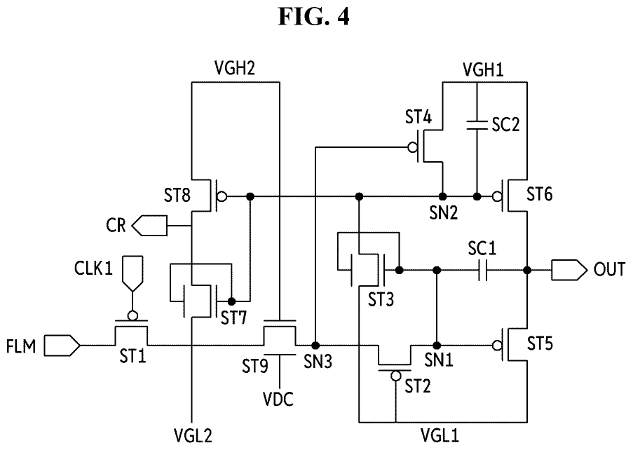

FIG. 4 is a circuit diagram illustrating a stage of the scan driver in the display device according to one or more embodiments.

Referring to FIG. 4, a stage STG may include first to ninth scan transistors ST1, ST2, ST3, ST4, ST5, ST6, ST7, ST8, and ST9 and first and second scan capacitors SC1 and SC2.

The first scan transistor ST1 may supply a start signal FLM to a drain electrode of the ninth scan transistor ST9 based on a first clock signal CLK1. A gate electrode of the first scan transistor ST1 may receive the first clock signal CLK1, a source electrode of the first scan transistor ST1 may receive the start signal FLM, and a drain electrode of the first scan transistor ST1 may be connected to the drain electrode of the ninth scan transistor ST9.

The second scan transistor ST2 may electrically connect a third scan node SN3 and a first scan node SN1 to each other based on a first gate low voltage VGL1. A gate electrode of the second scan transistor ST2 may receive the first gate low voltage VGL1, a source electrode of the second scan transistor ST2 may be connected to the third scan node SN3, and a drain electrode of the second scan transistor ST2 may be connected to the first scan node SN1. Here, the first scan node SN1 may be connected to the drain electrode of the second scan transistor ST2, a gate electrode of the third scan transistor ST3, a gate electrode of the fifth scan transistor ST5, and a first electrode of the first scan capacitor SC1. The third scan node SN3 may be connected to the source electrode of the second scan transistor ST2, a gate electrode of the fourth scan transistor ST4, and a source electrode of the ninth scan transistor ST9.

The third scan transistor ST3 may initialize a voltage of a second scan node SN2 to the first gate low voltage VGL1 based on a voltage of the first scan node SN1. The gate electrode of the third scan transistor ST3 may be connected to the first scan node SN1, a drain electrode of the third scan transistor ST3 may be connected to the second scan node SN2, and a source electrode of the third scan transistor ST3 may receive the first gate low voltage VGL1.

The third scan transistor ST3 may include a bias electrode. The bias electrode of the third scan transistor ST3 may be located below a semiconductor region of the third scan transistor ST3, and may overlap the semiconductor region. The bias electrode of the third scan transistor ST3 may be connected to the gate electrode of the third scan transistor ST3.

The fourth scan transistor ST4 may supply a first gate high voltage VGH1 to the second scan node SN2 based on a voltage of the third scan node SN3. The gate electrode of the fourth scan transistor ST4 may be connected to the third scan node SN3, a source electrode of the fourth scan transistor ST4 may receive the first gate high voltage VGH1, and a drain electrode of the fourth scan transistor ST4 may be connected to the second scan node SN2.

The fifth scan transistor ST5 may initialize a voltage of an output node OUT to the first gate low voltage VGL1 based on the voltage of the first scan node SN1. Here, the output node OUT may output a scan signal, and may supply the scan signal to the scan line of the display area DA. The gate electrode of the fifth scan transistor ST5 may be connected to the first scan node SN1, a source electrode of the fifth scan transistor ST5 may be connected to the output node OUT, and a drain electrode of the fifth scan transistor ST5 may receive the first gate low voltage VGL1.

The sixth scan transistor ST6 may supply the first gate high voltage VGH1 to the output node OUT based on a voltage of the second scan node SN2. A gate electrode of the sixth scan transistor ST6 may be connected to the second scan node SN2, a source electrode of the sixth scan transistor ST6 may receive the first gate high voltage VGH1, and a drain electrode of the sixth scan transistor ST6 may be connected to the output node OUT.

The seventh scan transistor ST7 may output a second gate low voltage VGL2 as a carry signal CR based on the voltage of the second scan node SN2. Here, an absolute value of the second gate low voltage VGL2 may be less than an absolute value of the first gate low voltage VGL1. A gate electrode of the seventh scan transistor ST7 may be connected to the second scan node SN2, a drain electrode of the seventh scan transistor ST7 may output the carry signal CR, and a source electrode of the seventh scan transistor ST7 may receive the second gate low voltage VGL2.

The seventh scan transistor ST7 may include a bias electrode. The bias electrode of the seventh scan transistor ST7 may be located below a semiconductor region of the seventh scan transistor ST7, and may overlap the semiconductor region. The bias electrode of the seventh scan transistor ST7 may be connected to the gate electrode of the seventh scan transistor ST7.

The eighth scan transistor ST8 may output a second gate high voltage VGH2 as a carry signal CR based on the voltage of the second scan node SN2. Here, the second gate high voltage VGH2 may be lower than the first gate high voltage VGH1. A gate electrode of the eighth scan transistor ST8 may be connected to the second scan node SN2, a source electrode of the eighth scan transistor ST8 may receive the second gate high voltage VGH2, and a drain electrode of the eighth scan transistor ST8 may output the carry signal CR.

The ninth scan transistor ST9 may electrically connect the drain electrode of the first scan transistor ST1 and the third scan node SN3 to each other based on the second gate high voltage VGH2. A gate electrode of the ninth scan transistor ST9 may receive the second gate high voltage VGH2, the drain electrode of the ninth scan transistor ST9 may be connected to the drain electrode of the first scan transistor ST1, and the source electrode of the ninth scan transistor ST9 may be connected to the third scan node SN3.

The ninth scan transistor ST9 may include a bias electrode. The bias electrode of the ninth scan transistor ST9 may be located below a semiconductor region of the ninth scan transistor ST9, and may overlap the semiconductor region. The bias electrode of the ninth scan transistor ST9 may receive a direct current voltage VDC. As an example, the direct current voltage VDC may be one of the first gate high voltage VGH1, the second gate high voltage VGH2, the first gate low voltage VGL1, and the second gate low voltage VGL2. As another example, the bias electrode of the ninth scan transistor ST9 may be electrically connected to the drain electrode of the ninth scan transistor ST9.

The first scan capacitor SC1 may be connected between the first scan node SN1 and the output node OUT, and may maintain a potential difference between the first scan node SN1 and the output node OUT.

The second scan capacitor SC2 may be connected between the second scan node SN2 and an input terminal of the first gate high voltage VGH1, and may maintain a potential difference between the second scan node SN2 and the input terminal of the first gate high voltage VGH1.

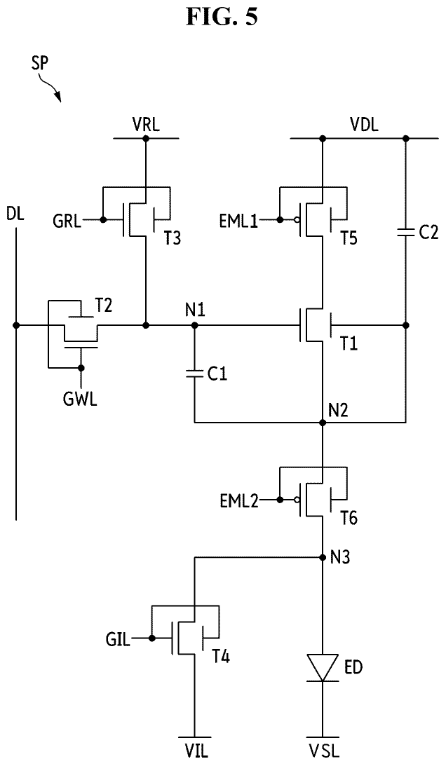

FIG. 5 is a circuit diagram illustrating a pixel of the display device according to one or more embodiments.

Referring to FIG. 5, the display panel 100 may include a plurality of pixels SP arranged along a plurality of rows and columns. Each of the plurality of pixels SP may be connected to a first gate line GWL, a second gate line GRL, a third gate line GIL, a first emission control line EML1, a second emission control line EML2, a data line DL, a reference voltage line VRL, a driving voltage line VDL, an initialization voltage line VIL, and a low potential line VSL.

The pixel SP may include a pixel circuit and a light-emitting element ED. The pixel circuit may include a first transistor T1, a second transistor T2, a third transistor T3, a fourth transistor T4, a fifth transistor T5, a sixth transistor T6, a first capacitor C1, and a second capacitor C2.

The first transistor T1 may include a gate electrode, a drain electrode, and a source electrode. The first transistor T1 may control a drain-source current (or a driving current) Ids according to a data voltage applied to the gate electrode. The driving current Ids flowing through a channel of the first transistor T1 may be proportional to the square of a difference between a voltage Vgs between the gate electrode and the source electrode and a threshold voltage Vth of the first transistor T1 (Ids=k×(Vgs−Vth)²). Here, k refers to a proportional coefficient determined by a structure and physical properties of the first transistor T1, Vgs refers to a gate-source voltage of the first transistor T1, and Vth refers to the threshold voltage of the first transistor T1. The gate electrode of the first transistor T1 may be connected to a first node N1, the drain electrode of the first transistor T1 may be connected to a drain electrode of the fifth transistor T5, and the source electrode of the first transistor T1 may be connected to a second node N2. The first transistor T1 may further include a bias electrode connected to the second node N2.

The light-emitting element ED may receive the driving current Ids to emit light. A light emission amount or luminance of the light-emitting element ED may be proportional to a magnitude of the driving current Ids.

The light-emitting element ED may be an organic light-emitting diode including a first electrode, a second electrode, and an organic light-emitting layer located between the first electrode and the second electrode. As another example, the light-emitting element ED may be an inorganic light-emitting element including a first electrode, a second electrode, and an inorganic semiconductor located between the first electrode and the second electrode. As still another example, the light-emitting element ED may be a quantum dot light-emitting element including a first electrode, a second electrode, and a quantum dot light-emitting layer located between the first electrode and the second electrode. As still another example, the light-emitting element ED may be a micro light-emitting diode.

The first electrode of the light-emitting element ED may be connected to a third node N3. The first electrode of the light-emitting element ED may be connected to a drain electrode of the fourth transistor T4 and a drain electrode of the sixth transistor T6 through the third node N3. The second electrode of the light-emitting element ED may be connected to the low potential line VSL to receive a low potential voltage from the low potential line VSL.

The second transistor T2 may be turned on by a first gate signal of the first gate line GWL to electrically connect the data line DL and the first node N1, which is the gate electrode of the first transistor T1, to each other. The second transistor T2 may be turned on based on the first gate signal to supply a data voltage to the first node N1. A gate electrode of the second transistor T2 may be connected to the first gate line GWL, a drain electrode of the second transistor T2 may be connected to the data line DL, and a source electrode of the second transistor T2 may be connected to the first node N1. The second transistor T2 may further include a bias electrode connected to the first gate line GWL.

The third transistor T3 may be turned on by a second gate signal of the second gate line GRL to electrically connect the reference voltage line VRL and the first node N1, which is the gate electrode of the first transistor T1, to each other. The third transistor T3 may be turned on based on the second gate signal to supply a reference voltage to the first node N1. A gate electrode of the third transistor T3 may be connected to the second gate line GRL, a drain electrode of the third transistor T3 may be connected to the reference voltage line VRL, and a source electrode of the third transistor T3 may be connected to the first node N1. The third transistor T3 may further include a bias electrode connected to the second gate line GRL.

The fourth transistor T4 may be turned on by a third gate signal of the third gate line GIL to electrically connect the third node N3, which is the first electrode of the light-emitting element ED, and the initialization voltage line VIL to each other. The fourth transistor T4 may be turned on based on the third gate signal to discharge the first electrode of the light-emitting element ED to an initialization voltage. A gate electrode of the fourth transistor T4 may be connected to the third gate line GIL, the drain electrode of the fourth transistor T4 may be connected to the third node N3, and a source electrode of the fourth transistor T4 may be connected to the initialization voltage line VIL. The fourth transistor T4 may further include a bias electrode connected to the third gate line GIL.

The fifth transistor T5 may be turned on by a first emission signal of the first emission control line EML1 to electrically connect the driving voltage line VDL and the drain electrode of the first transistor T1 to each other. A gate electrode of the fifth transistor T5 may be connected to the first emission control line EML1, a source electrode of the fifth transistor T5 may be connected to the driving voltage line VDL, and the drain electrode of the fifth transistor T5 may be connected to the drain electrode of the first transistor T1. The fifth transistor T5 may further include a bias electrode connected to the first emission control line EML1.

The sixth transistor T6 may be turned on by a second emission signal of the second emission control line EML2 to electrically connect the second node N2 and the third node N3 to each other. Here, the second emission signal may be an inverted signal of the first emission signal, but is not limited thereto. A gate electrode of the sixth transistor T6 may be connected to the second emission control line EML2, a source electrode of the sixth transistor T6 may be connected to the second node N2, and the drain electrode of the sixth transistor T6 may be connected to the third node N3. The sixth transistor T6 may further include a bias electrode connected to the second emission control line EML2.

Each of the first to fourth transistors T1, T2, T3, and T4 may include an oxide-based semiconductor region. For example, each of the first to fourth transistors T1, T2, T3, and T4 may have a coplanar structure in which the gate electrode is located above the oxide-based semiconductor region. The transistor including the oxide-based semiconductor region may have excellent leakage current characteristics, and may be driven at a low frequency to reduce power consumption. Accordingly, the display device 10 may reduce or prevent a leakage current from flowing inside the pixel and stably maintain a voltage inside the pixel, by including the first to fourth transistors T1, T2, T3, and T4 that have the excellent leakage current characteristics.

Each of the first to fourth transistors T1, T2, T3, and T4 may correspond to an N-type transistor. For example, each of the first to fourth transistors T1, T2, T3, and T4 may output a current introduced into a first electrode to a second electrode based on a gate high voltage applied to the gate electrode.

Each of the fifth and sixth transistors T5 and T6 may include a silicon-based semiconductor region. For example, each of the fifth and sixth transistors T5 and T6 may include a semiconductor region made of low temperature polycrystalline silicon (LTPS). The semiconductor region made of the low temperature polycrystalline silicon may have high electron mobility and excellent turn-on characteristics. Accordingly, the display panel 100 may stably and efficiently drive the plurality of pixels SP by including the fifth and sixth transistors T5 and T6 that have the excellent turn-on characteristics.

Each of the fifth and sixth transistors T5 and T6 may correspond to a P-type transistor. For example, each of the fifth and sixth transistors T5 and T6 may output a current introduced into a first electrode to a second electrode based on a gate low voltage applied to the gate electrode.

The first capacitor C1 may be connected between the first node N1, which is the gate electrode of the first transistor T1, and the second node N2, which is the source electrode of the first transistor T1. For example, a first electrode of the first capacitor C1 is connected to the first node N1 and a second electrode of the first capacitor C1 is connected to the second node N2, such that a potential difference between the gate electrode and the source electrode of the first transistor T1 may be maintained.

The second capacitor C2 may be electrically connected between the driving voltage line VDL and the second node N2, which is the source electrode of the first transistor T1. For example, a first electrode of the second capacitor C2 is connected to the driving voltage line VDL and a second electrode of the second capacitor C2 is electrically connected to the second node N2, such that a potential difference between the driving voltage line VDL and the source electrode of the first transistor T1 may be maintained.

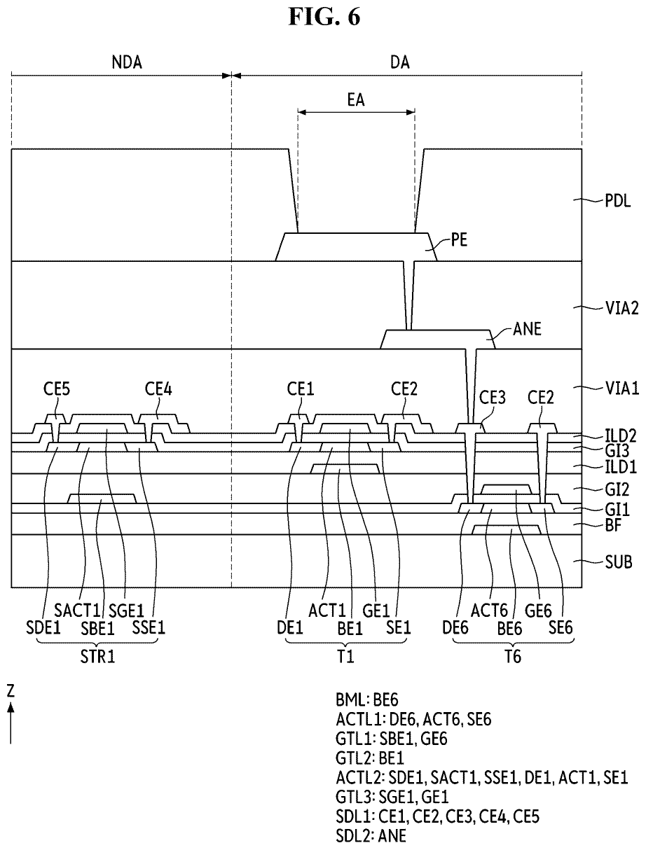

FIG. 6 is a cross-sectional view illustrating the display device according to one or more embodiments.

Referring to FIG. 6, the display panel 100 may include a substrate SUB, a metal layer BML, a buffer layer BF, a first active layer ACTL1, a first gate-insulating layer GI1, a first gate layer GTL1, a second gate-insulating layer GI2, a second gate layer GTL2, a first interlayer insulating layer ILD1, a second active layer ACTL2, a third gate-insulating layer GI3, a third gate layer GTL3, a second interlayer insulating layer ILD2, a first source metal layer SDL1, a first via layer VIA1, a second source metal layer SDL2, a second via layer VIA2, a pixel electrode PE, and a pixel-defining film PDL.

The pixel SP may be located in the display area DA and may include the first transistor T1 and the sixth transistor T6 illustrated in FIG. 5, and the stage STG of the scan driver 800 may be located in the non-display area NDA, and may include a first oxide transistor STR1. Here, the first oxide transistor STR1 may be one of the third scan transistor ST3, the seventh scan transistor ST7, and/or the ninth scan transistor ST9 of the stage STG illustrated in FIG. 4. As another example, the first oxide transistor STR1 of the stage STG may be located in the display area DA.

The substrate SUB may be a base substrate or a base member. The substrate SUB may be a flexible substrate that may be bent, folded, and rolled. As an example, the substrate SUB may include a polymer resin, such as polyimide (PI), but is not limited thereto. As another example, the substrate SUB may include a glass material or a metal material.

The metal layer BML may be located on the substrate SUB (as used herein, “located on” may mean “above”). The metal layer BML may include a bias electrode BE6 of the sixth transistor T6. The bias electrode BE6 of the sixth transistor T6 may be located below a semiconductor region ACT6 of the sixth transistor T6, and may overlap the semiconductor region ACT6. In one or more embodiments, the bias electrode of the fifth transistor T5 of FIG. 5 may be located at the metal layer BML.

The buffer layer BF may be located on the metal layer BML. For example, the buffer layer BF may include an inorganic film capable of reducing or preventing permeation of air or moisture. For example, the buffer layer BF may include a plurality of inorganic films that are alternately stacked.

The first active layer ACTL1 may be located on the buffer layer BF. The first active layer ACTL1 may include a silicon-based material. For example, the first active layer ACTL1 may be made of low temperature polycrystalline silicon (LTPS). The first active layer ACTL1 may include the semiconductor region ACT6, a source electrode SE6, and a drain electrode DE6 of the sixth transistor T6.

The first gate-insulating layer GI1 may be located on the first active layer ACTL1. The first gate-insulating layer GI1 may insulate the first active layer ACTL1 and the first gate layer GTL1 from each other.

The first gate layer GTL1 may be located on the first gate-insulating layer GI1. The first gate layer GTL1 may include a bias electrode SBE1 of the first oxide transistor STR1 and a gate electrode GE6 of the sixth transistor T6. The bias electrode SBE1 of the first oxide transistor STR1 may be located below a semiconductor region SACT1 of the first oxide transistor STR1 and may overlap the semiconductor region SACT1.

The second gate-insulating layer GI2 may be located on the first gate layer GTL1. The second gate-insulating layer GI2 may insulate the first gate layer GTL1 and the second gate layer GTL2 from each other.

The second gate layer GTL2 may be located on the second gate-insulating layer GI2. The second gate layer GTL2 may include a bias electrode BE1 of the first transistor T1. The bias electrode BE1 of the first transistor T1 may be located below a semiconductor region ACT1 of the first transistor T1, and may overlap the semiconductor region ACT1.

The first interlayer insulating layer ILD1 may be located on the second gate layer GTL2. The first interlayer insulating layer ILD1 may insulate the second gate layer GTL2 and the second active layer ACTL2 from each other.

The second active layer ACTL2 may be located on the first interlayer insulating layer ILD1. The second active layer ACTL2 may include an oxide-based material. The second active layer ACTL2 may include the semiconductor region ACT1, a drain electrode DE1, a source electrode SE1 of the first transistor T1 and the semiconductor region SACT1, a drain electrode SDE1, and a source electrode SSE1 of the first oxide transistor STR1.

The semiconductor region ACT1 of the first transistor T1 of the pixel SP and the semiconductor region SACT1 of the first oxide transistor STR1 of the stage STG may be located at the same layer, and the bias electrode BE1 of the first transistor T1 and the bias electrode SBE1 of the first oxide transistor STR1 may be located at different layers. Because the scan driver 800 includes the bias electrode SBE1 of the first oxide transistor STR1 located at a different layer from the bias electrode BE1 of the first transistor T1, the scan driver 800 may adjust an influence of a bias voltage applied to the bias electrode SBE1 to control a threshold voltage of the first oxide transistor STR1, and may suitably perform charging and discharging of the first scan node SN1 of FIG. 4 to improve reliability of the scan driver 800.

The third gate-insulating layer GI3 may be located on the second active layer ACTL2. The third gate-insulating layer GI3 may insulate the second active layer ACTL2 and the third gate layer GTL3 from each other.

The third gate layer GTL3 may be located on the third gate-insulating layer GI3. The third gate layer GTL3 may include a gate electrode SGE1 of the first oxide transistor STR1 and a gate electrode GE1 of the first transistor T1.

The second interlayer insulating layer ILD2 may be located on the third gate layer GTL3. The second interlayer insulating layer ILD2 may insulate the third gate layer GTL3 and the first source metal layer SDL1 from each other.

The first source metal layer SDL1 may be located on the second interlayer insulating layer ILD2. The first source metal layer SDL1 may include first to fifth connection electrodes CE1, CE2, CE3, CE4, and CE5. The first connection electrode CE1 may be connected to the drain electrode DE1 of the first transistor T1. The second connection electrode CE2 may electrically connect the source electrode SE1 of the first transistor T1 and the source electrode SE6 of the sixth transistor T6 to each other. The third connection electrode CE3 may electrically connect the drain electrode DE6 of the sixth transistor T6 and an anode connection electrode ANE to each other. The fourth connection electrode CE4 may be connected to the source electrode SSE1 of the first oxide transistor STR1. The fifth connection electrode CE5 may be connected to the drain electrode SDE1 of the first oxide transistor STR1.

The first via layer VIA1 may be located on the first source metal layer SDL1. The first via layer VIA1 may insulate the first source metal layer SDL1 and the second source metal layer SDL2 from each other.

The second source metal layer SDL2 may be located on the first via layer VIA1. The second source metal layer SDL2 may include the anode connection electrode ANE. The anode connection electrode ANE may electrically connect the third connection electrode CE3 and the pixel electrode PE to each other.

The second via layer VIA2 may be located on the second source metal layer SDL2. The second via layer VIA2 may insulate the second source metal layer SDL2 and the pixel electrode PE from each other.

The pixel electrode PE may be located on the second via layer VIA2. The pixel electrode PE may be exposed through an emission area EA. The pixel electrode PE may be the first electrode of the light-emitting element ED of FIG. 5.

The pixel-defining film PDL may be located on the second via layer VIA2. The pixel-defining film PDL may define a plurality of emission areas EA. The pixel-defining film PDL may include an organic insulating material, such as polyimide (PI).

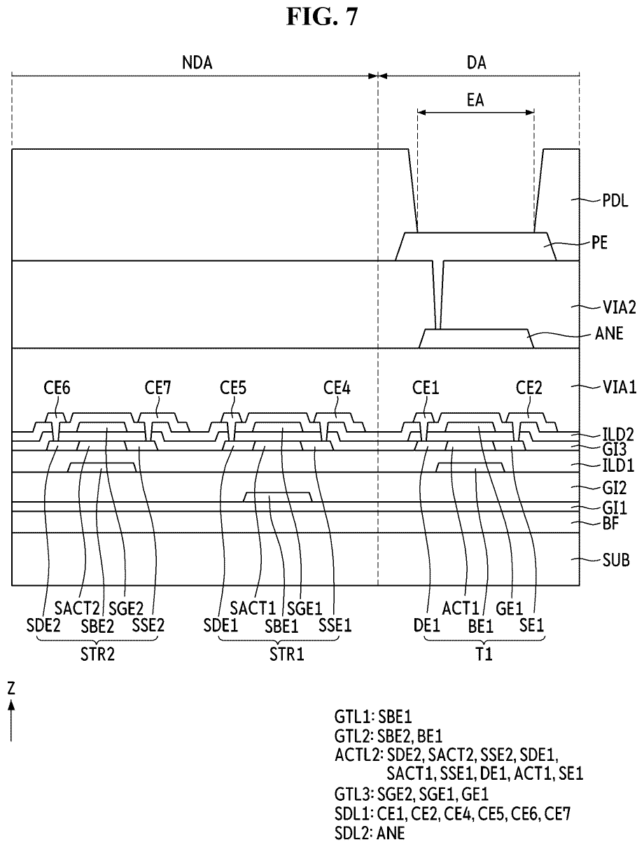

FIG. 7 is a cross-sectional view illustrating a display device according to one or more other embodiments. A display device of FIG. 7 is different from the display device of FIG. 6 in that it further includes a second oxide transistor STR2, and the same configurations as the configurations described above will be briefly described or a repeated description thereof will be omitted.

Referring to FIG. 7, the display panel 100 may include a substrate SUB, a metal layer BML, a buffer layer BF, a first active layer ACTL1, a first gate-insulating layer GI1, a first gate layer GTL1, a second gate-insulating layer GI2, a second gate layer GTL2, a first interlayer insulating layer ILD1, a second active layer ACTL2, a third gate-insulating layer GI3, a third gate layer GTL3, a second interlayer insulating layer ILD2, a first source metal layer SDL1, a first via layer VIA1, a second source metal layer SDL2, a second via layer VIA2, a pixel electrode PE, and a pixel-defining film PDL.

The pixel SP may be located in the display area DA and may include the first transistor T1 illustrated in FIG. 5, and the stage STG of the scan driver 800 may be located in the non-display area NDA, and may include a first oxide transistor STR1 and a second oxide transistor STR2. Here, the first oxide transistor STR1 may be one of the third scan transistor ST3, the seventh scan transistor ST7, and/or the ninth scan transistor ST9 of the stage STG illustrated in FIG. 4, and the second oxide transistor STR2 may be another of the third scan transistor ST3, the seventh scan transistor ST7, and/or the ninth scan transistor ST9.

The first gate layer GTL1 may include a bias electrode SBE1 of the first oxide transistor STR1. The bias electrode SBE1 of the first oxide transistor STR1 may be located below a semiconductor region SACT1 of the first oxide transistor STR1, and may overlap the semiconductor region SACT1.

The second gate layer GTL2 may include a bias electrode SBE2 of the second oxide transistor STR2, and a bias electrode BE1 of the first transistor T1. The bias electrode SBE2 of the second oxide transistor STR2 may be located below a semiconductor region SACT2 of the second oxide transistor STR2, and may overlap the semiconductor region SACT2. The bias electrode BE1 of the first transistor T1 may be located below a semiconductor region ACT1 of the first transistor T1, and may overlap the semiconductor region ACT1.

The second active layer ACTL2 may include an oxide-based material. The second active layer ACTL2 may include the semiconductor region ACT1, a drain electrode DE1, a source electrode SE1 of the first transistor T1, the semiconductor region SACT1, a drain electrode SDE1, and a source electrode SSE1 of the first oxide transistor STR1, and the semiconductor region SACT2, a drain electrode SDE2, and a source electrode SSE2 of the second oxide transistor STR2.

The semiconductor region ACT1 of the first transistor T1 of the pixel SP and the semiconductor region SACT1 of the first oxide transistor STR1 and the semiconductor region SACT2 of the second oxide transistor STR2 of the stage STG may be located at the same layer, and the bias electrode SBE1 of the first oxide transistor STR1 and the bias electrode SBE2 of the second oxide transistor STR2 may be located at different layers. For example, the first oxide transistor STR1 may be the ninth scan transistor ST9 of FIG. 4, and the second oxide transistor STR2 may be the third or seventh scan transistor T3 or T7 of FIG. 4, but the present disclosure is not limited thereto. The bias electrode SBE1 of the first oxide transistor STR1 is located at the first gate layer GTL1, such that an influence of a bias voltage applied to the bias electrode SBE1 may be relatively small, and the bias electrode SBE2 of the second oxide transistor STR2 is located at the second gate layer GTL2, such that an influence of a bias voltage applied to the bias electrode SBE2 may be relatively great. Accordingly, the scan driver 800 may adjust the influences of the bias voltages applied to the bias electrode SBE1 of the first oxide transistor STR1 and the bias electrode SBE2 of the second oxide transistor STR2 to control a threshold voltage of each of the first and second oxide transistors STR1 and STR2, and may suitably perform charging and discharging of the first scan node SN1 of FIG. 4 to improve reliability of the scan driver 800.

The third gate layer GTL3 may include a gate electrode SGE1 of the first oxide transistor STR1, a gate electrode SGE2 of the second oxide transistor STR2, and a gate electrode GE1 of the first transistor T1.

The first source metal layer SDL1 may include first and second, and fourth to seventh connection electrodes CE1, CE2, CE4, CE5, CE6, and CE7. The sixth connection electrode CE6 may be connected to the drain electrode SDE2 of the second oxide transistor STR2. The seventh connection electrode CE7 may be connected to the source electrode SSE1 of the second oxide transistor STR2.

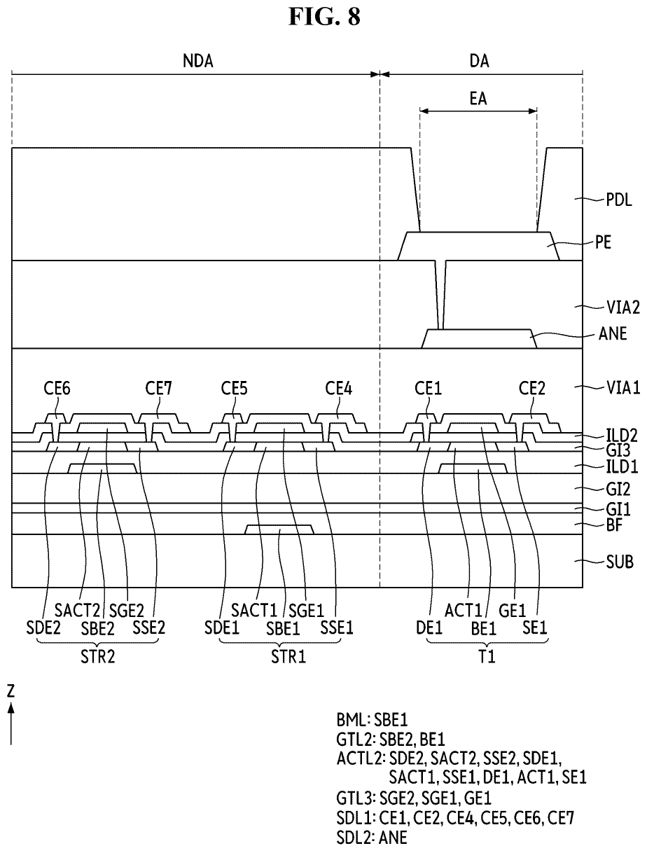

FIG. 8 is a cross-sectional view illustrating a display device according to still one or more other embodiments. A display device of FIG. 8 is different from the display device of FIG. 7 with respect to a layer of a bias electrode SBE1 of a first oxide transistor STR1, and the same configurations as the configurations described above will be briefly described or a repeated description thereof will be omitted.

Referring to FIG. 8, the display panel 100 may include a substrate SUB, a metal layer BML, a buffer layer BF, a first active layer ACTL1, a first gate-insulating layer GI1, a first gate layer GTL1, a second gate-insulating layer GI2, a second gate layer GTL2, a first interlayer insulating layer ILD1, a second active layer ACTL2, a third gate-insulating layer GI3, a third gate layer GTL3, a second interlayer insulating layer ILD2, a first source metal layer SDL1, a first via layer VIA1, a second source metal layer SDL2, a second via layer VIA2, a pixel electrode PE, and a pixel-defining film PDL.

The pixel SP may be located in the display area DA and may include the first transistor T1 illustrated in FIG. 5, and the stage STG of the scan driver 800 may be located in the non-display area NDA, and may include a first oxide transistor STR1 and a second oxide transistor STR2. Here, the first oxide transistor STR1 may be one of the third scan transistor ST3, the seventh scan transistor ST7, and/or the ninth scan transistor ST9 of the stage STG illustrated in FIG. 4, and the second oxide transistor STR2 may be another of the third scan transistor ST3, the seventh scan transistor ST7, and/or the ninth scan transistor ST9.

The metal layer BML may include a bias electrode SBE1 of the first oxide transistor STR1, and the second gate layer GTL2 may include a bias electrode SBE2 of the second oxide transistor STR2 and a bias electrode BE1 of the first transistor T1.

For example, the first oxide transistor STR1 may be the ninth scan transistor ST9 of FIG. 4, and the second oxide transistor STR2 may be the third or seventh scan transistor T3 or T7 of FIG. 4, but the present disclosure is not limited thereto. The bias electrode SBE1 of the first oxide transistor STR1 of FIG. 8 is located at the metal layer BML, such that an influence of a bias voltage applied to the bias electrode SBE1 may be relatively less than that of the bias voltage applied to the bias electrode SBE1 of the first oxide transistor STR1 of FIG. 7. The bias electrode SBE2 of the second oxide transistor STR2 is located at the second gate layer GTL2, such that an influence of a bias voltage applied to the bias electrode SBE2 may be relatively great. Accordingly, the scan driver 800 may adjust the influences of the bias voltages applied to the bias electrode SBE1 of the first oxide transistor STR1 and the bias electrode SBE2 of the second oxide transistor STR2 to control a threshold voltage of each of the first and second oxide transistors STR1 and STR2, and may suitably perform charging and discharging of the first scan node SN1 of FIG. 4 to improve reliability of the scan driver 800.

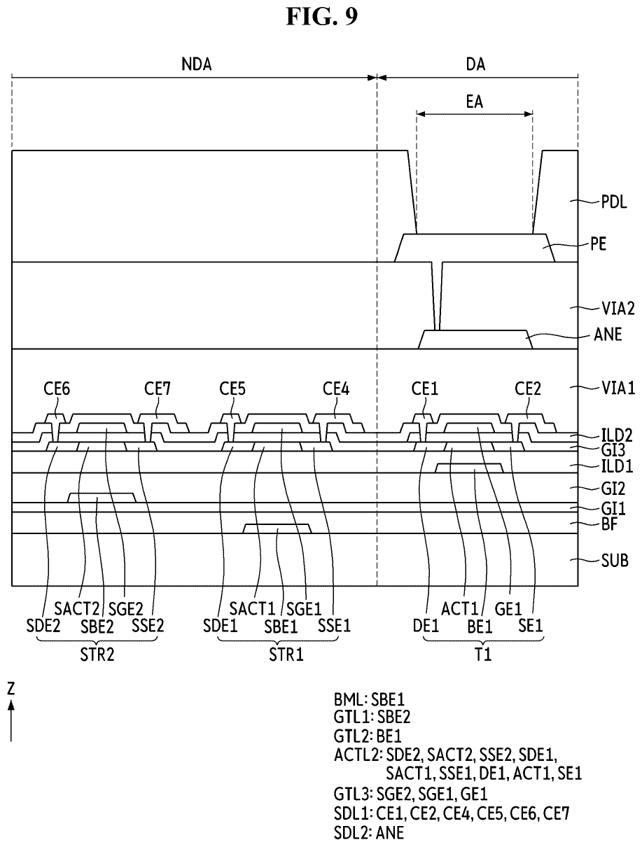

FIG. 9 is a cross-sectional view illustrating a display device according to still one or more other embodiments. A display device of FIG. 9 is different from the display device of FIG. 8 with respect to a layer of a bias electrode SBE2 of a second oxide transistor STR2, and the same configurations as the configurations described above will be briefly described or a repeated description thereof will be omitted.

Referring to FIG. 9, the display panel 100 may include a substrate SUB, a metal layer BML, a buffer layer BF, a first active layer ACTL1, a first gate-insulating layer GI1, a first gate layer GTL1, a second gate-insulating layer GI2, a second gate layer GTL2, a first interlayer insulating layer ILD1, a second active layer ACTL2, a third gate-insulating layer GI3, a third gate layer GTL3, a second interlayer insulating layer ILD2, a first source metal layer SDL1, a first via layer VIA1, a second source metal layer SDL2, a second via layer VIA2, a pixel electrode PE, and a pixel-defining film PDL.

The pixel SP may be located in the display area DA and may include the first transistor T1 illustrated in FIG. 5, and the stage STG of the scan driver 800 may be located in the non-display area NDA, and may include a first oxide transistor STR1 and a second oxide transistor STR2. Here, the first oxide transistor STR1 may be one of the third scan transistor ST3, the seventh scan transistor ST7, and/or the ninth scan transistor ST9 of the stage STG illustrated in FIG. 4, and the second oxide transistor STR2 may be another of the third scan transistor ST3, the seventh scan transistor ST7, and/or the ninth scan transistor ST9.

The metal layer BML may include a bias electrode SBE1 of the first oxide transistor STR1, the first gate layer GTL1 may include a bias electrode SBE2 of the second oxide transistor STR2, and the second gate layer GTL2 may include a bias electrode BE1 of the first transistor T1.

For example, the first oxide transistor STR1 may be the ninth scan transistor ST9 of FIG. 4, and the second oxide transistor STR2 may be the third or seventh scan transistor T3 or T7 of FIG. 4, but the present disclosure is not limited thereto. The bias electrode SBE1 of the first oxide transistor STR1 of FIG. 9 is located at the metal layer BML, such that an influence of a bias voltage applied to the bias electrode SBE1 may be relatively less than that of the bias voltage applied to the bias electrode SBE1 of the first oxide transistor STR1 of FIG. 7. The bias electrode SBE2 of the second oxide transistor STR2 of FIG. 9 is located at the first gate layer GTL1, such that an influence of a bias voltage applied to the bias electrode SBE2 may be relatively less than that of the bias voltage applied to the bias electrode SBE2 of the second oxide transistor STR2 of FIG. 7. The influence of the bias voltage applied to the bias electrode SBE2 of the second oxide transistor STR2 may be relatively greater than that of the bias voltage applied to the bias electrode SBE1 of the first oxide transistor STR1. Accordingly, the scan driver 800 may adjust the influences of the bias voltages applied to the bias electrode SBE1 of the first oxide transistor STR1 and the bias electrode SBE2 of the second oxide transistor STR2 to control a threshold voltage of each of the first and second oxide transistors STR1 and STR2, and may suitably perform charging and discharging of the first scan node SN1 of FIG. 4 to improve reliability of the scan driver 800.

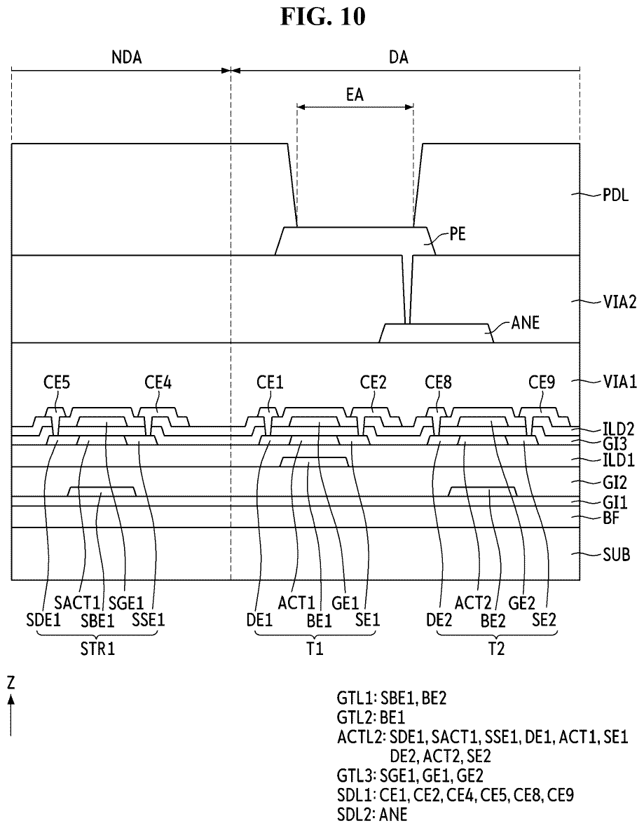

FIG. 10 is a cross-sectional view illustrating a display device according to still one or more other embodiments. A display device of FIG. 10 is different from the display device of FIG. 6 in that it further includes a second transistor T2, and the same configurations as the configurations described above will be briefly described or a repeated description thereof will be omitted.

Referring to FIG. 10, the display panel 100 may include a substrate SUB, a metal layer BML, a buffer layer BF, a first active layer ACTL1, a first gate-insulating layer GI1, a first gate layer GTL1, a second gate-insulating layer GI2, a second gate layer GTL2, a first interlayer insulating layer ILD1, a second active layer ACTL2, a third gate-insulating layer GI3, a third gate layer GTL3, a second interlayer insulating layer ILD2, a first source metal layer SDL1, a first via layer VIA1, a second source metal layer SDL2, a second via layer VIA2, a pixel electrode PE, and a pixel-defining film PDL.

The pixel SP may be located in the display area DA and may include the first and second transistors T1 and T2 illustrated in FIG. 5, and the stage STG of the scan driver 800 may be located in the non-display area NDA, and may include a first oxide transistor STR1. Here, the first oxide transistor STR1 may be one of the third scan transistor ST3, the seventh scan transistor ST7, and/or the ninth scan transistor ST9 of the stage STG illustrated in FIG. 4.

The first gate layer GTL1 may include a bias electrode SBE1 of the first oxide transistor STR1 and a bias electrode BE2 of the second transistor T2. The bias electrode BE2 of the second transistor T2 may be located below a semiconductor region ACT2 of the second transistor T2, and may overlap the semiconductor region ACT2.

The second gate layer GTL2 may include a bias electrode BE1 of the first transistor T1.

The second active layer ACTL2 may include an oxide-based material. The second active layer ACTL2 may include a semiconductor region ACT1, a drain electrode DE1, a source electrode SE1 of the first transistor T1, the semiconductor region ACT2, a drain electrode DE2, a source electrode SE2 of the second transistor T2, and a semiconductor region SACT1, a drain electrode SDE1, and a source electrode SSE1 of the first oxide transistor STR1.

The semiconductor region ACT1 of the first transistor T1 and the semiconductor region ACT2 of the second transistor T2 of the pixel SP and the semiconductor region SACT1 of the first oxide transistor STR1 of the stage STG may be located at the same layer, and the bias electrode BE1 of the first transistor T1 and the bias electrode BE2 of the second transistor T2 may be located at different layers. The bias electrode BE1 of the first transistor T1 is located at the second gate layer GTL1, such that an influence of a bias voltage applied to the bias electrode BE1 may be relatively great, and the bias electrode BE2 of the second transistor T2 may be located at the first gate layer GTL1, such that an influence of a bias voltage applied to the bias electrode BE2 may be relatively small. Accordingly, the display device 10 may adjust the influences of the bias voltages applied to the bias electrode BE1 of the first transistor T1 and the bias electrode BE2 of the second transistor T2 to control a threshold voltage of each of the first and second transistors T1 and T2, and may improve resolution of the pixels SP.

The third gate layer GTL3 may include a gate electrode SGE1 of the first oxide transistor STR1, a gate electrode GE1 of the first transistor T1, and a gate electrode GE2 of the second transistor T2.

The first source metal layer SDL1 may include first, second, fourth, fifth, eighth, and ninth connection electrodes CE1, CE2, CE4, CE5, CE8, and CE9. The eighth connection electrode CE8 may be connected to the drain electrode DE2 of the second transistor T2. The ninth connection electrode CE9 may be connected to the source electrode SE2 of the second transistor T2.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a pixel comprising a light-emitting element, and a first transistor configured to supply a driving current to the light-emitting element;
a scan driver comprising a first oxide transistor, and configured to supply a scan signal to the pixel;
a first active layer above a substrate, and comprising a first material;
a first gate layer above the first active layer;
a second gate layer above the first gate layer; and
a second active layer above the second gate layer, comprising a second material that is different from the first material, and comprising a semiconductor region of the first transistor and a semiconductor region of the first oxide transistor,
wherein a bias electrode of the first transistor and a bias electrode of the first oxide transistor are at different layers.

2. The display device of claim 1, wherein the bias electrode of the first transistor is at the second gate layer, and the bias electrode of the first oxide transistor is at the first gate layer.

3. The display device of claim 1, wherein the scan driver further comprises a second oxide transistor comprising a semiconductor region at the second active layer, and
wherein a bias electrode of the second oxide transistor and the bias electrode of the first oxide transistor are at different layers.

4. The display device of claim 3, wherein the bias electrode of the second oxide transistor is at the second gate layer, and the bias electrode of the first oxide transistor is at the first gate layer.

5. The display device of claim 3, further comprising a metal layer between the substrate and the first active layer,
wherein the bias electrode of the second oxide transistor is at the first gate layer, and the bias electrode of the first oxide transistor is at the metal layer.

6. The display device of claim 3, further comprising a metal layer between the substrate and the first active layer,
wherein the bias electrode of the first transistor is at the second gate layer, and the bias electrode of the first oxide transistor is at the metal layer.

7. The display device of claim 3, wherein the scan driver further comprises:
a fifth scan transistor configured to supply a first gate low voltage to an output node for outputting the scan signal based on a voltage of a first scan node;
a sixth scan transistor configured to supply a first gate high voltage to the output node based on a voltage of a second scan node;
a third scan transistor configured to initialize the voltage of the second scan node to the first gate low voltage based on the voltage of the first scan node;
a second scan transistor configured to electrically connect the first scan node to a third scan node based on the first gate low voltage; and
a first scan transistor configured to supply a start signal to the third scan node based on a first clock signal.

8. The display device of claim 7, wherein the first oxide transistor is the first scan transistor, and the second oxide transistor is the third scan transistor.

9. The display device of claim 7, wherein the scan driver further comprises a seventh scan transistor for outputting a second gate low voltage as a carry signal based on the voltage of the second scan node, the second gate low voltage having an absolute value that is lower than an absolute value of the first gate low voltage.

10. The display device of claim 9, wherein the first oxide transistor is the first scan transistor, and the second oxide transistor is the third or seventh scan transistor.

11. The display device of claim 1, wherein the pixel further comprises:
a second transistor configured to supply a data voltage to a first node that is a gate electrode of the first transistor;
a third transistor configured to supply a reference voltage to the first node;
a fourth transistor configured to discharge a first electrode of the light-emitting element to an initialization voltage;
a fifth transistor configured to supply a driving voltage to a drain electrode of the first transistor; and
a sixth transistor configured to electrically connect a second node that is a source electrode of the first transistor and a third node that is the first electrode of the light-emitting element to each other.

12. The display device of claim 11, wherein a semiconductor region of the second transistor is at the second active layer, and
wherein the bias electrode of the first transistor and a bias electrode of the second transistor are at different layers.

13. The display device of claim 11, wherein the bias electrode of the first transistor is at the second gate layer, and
wherein a bias electrode of the second transistor is at the first gate layer.

14. An electronic device comprising a display device comprising:
a light-emitting element;
a first transistor configured to supply a driving current to the light-emitting element;
a second transistor configured to supply a data voltage to a first node that is a gate electrode of the first transistor;
a third transistor configured to supply a reference voltage to the first node;
a fourth transistor configured to discharge a first electrode of the light-emitting element to an initialization voltage;
a fifth transistor configured to supply a driving voltage to a drain electrode of the first transistor;
a sixth transistor configured to electrically connect a second node that is a source electrode of the first transistor and a third node that is the first electrode of the light-emitting element to each other;
a first active layer above a substrate, and comprising a semiconductor region of the fifth transistor and a semiconductor region of the sixth transistor;
a first gate layer above the first active layer;
a second gate layer above the first gate layer; and
a second active layer above the second gate layer, and comprising a semiconductor region of the first transistor and a semiconductor region of the second transistor,
wherein a bias electrode of the first transistor and a bias electrode of the second transistor are at different layers.

15. The electronic device of claim 14, wherein the bias electrode of the first transistor is at the second gate layer, and the bias electrode of the second transistor is at the first gate layer, and
wherein the display device further comprises a metal layer between the substrate and the first active layer,
wherein a bias electrode of the fifth transistor and a bias electrode of the sixth transistor are at the metal layer.

16. The electronic device of claim 14, wherein the electronic device comprises a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, a head-mounted display (HMD), a virtual reality (VR) device, or an augmented reality (AR) device.

17. A scan driver comprising:
a fifth scan transistor configured to supply a first gate low voltage to an output node based on a voltage of a first scan node, the output node for outputting a scan signal;
a sixth scan transistor configured to supply a first gate high voltage to the output node based on a voltage of a second scan node;
a third scan transistor configured to initialize the voltage of the second scan node to the first gate low voltage based on the voltage of the first scan node;
a second scan transistor configured to electrically connect the first scan node to a third scan node based on the first gate low voltage;
a first scan transistor configured to supply a start signal to the third scan node based on a second gate high voltage that is lower than the first gate high voltage; and
a seventh scan transistor configured to output a second gate low voltage as a carry signal based on the voltage of the second scan node, the second gate low voltage having an absolute value that is lower than an absolute value of the first gate low voltage,
wherein a bias electrode of the first scan transistor and a bias electrode of the seventh scan transistor are at different layers.

18. The scan driver of claim 17, further comprising:
a first active layer above a substrate, and comprising a semiconductor region of the first scan transistor and a semiconductor region of the sixth scan transistor;
a first gate layer above the first active layer;
a second gate layer above the first gate layer; and
a second active layer above the second gate layer, and comprising a semiconductor region of the first scan transistor and a semiconductor region of the seventh scan transistor.

19. The scan driver of claim 18, wherein the bias electrode of the first scan transistor is at the first gate layer, and
wherein the bias electrode of the seventh scan transistor is at the second gate layer.

20. The scan driver of claim 18, further comprising a metal layer between the substrate and the first active layer,
wherein the bias electrode of the first scan transistor is at the metal layer, and
wherein the bias electrode of the seventh scan transistor is at the second gate layer.
